(19) United States
(12) Patent Application Publication
(10) Pub. No.: US 2005/0242444 A1
(43) Pub. Date: Nov. 3, 2005

(54) Integrated circuit having a strengthened passivation structure

(75) Inventors: Kun-Ming Huang, Taipei City (TW); Chen-Fu Hsu, Tai chung City (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 10/965,623

(22) Filed: Oct. 14, 2004

Related U.S. Application Data
(60) Provisional application No. 60/567,107, filed on Apr. 30, 2004.

(51) Int. Cl. H01L 29/40

(52) U.S. Cl. 257/778; 257/779; 257/781

(57) ABSTRACT

Provided is an integrated circuit (IC) having a strengthened passivation layer. In one example, the IC comprises a semiconductor substrate, a multilevel interconnect structure formed on the semiconductor substrate, and a multilayer passivation structure overlying the multilevel interconnect structure. At least one metal line of the multilevel interconnect structure forms a taper profile.

### CROSS-REFERENCE

This application is related to, and claims priority of, U.S. Provisional Patent Application Ser. No. 60/567,107, filed on Apr. 30, 2004.

### BACKGROUND

Chip On Glass (COG) technology uses an anisotropic conductive film (ACF) to mount an integrated circuit (IC) chip to a glass substrate. For example, COG is broadly used in liquid crystal (LC) drive ICs (LDI) to directly bond the LDI to the glass substrate of a liquid crystal display (LCD).

However, acid material in the ACF may attack top metal lines through defects in a passivation layer overlying the top metal lines and induce failures of the IC chip, especially after qualification and reliability tests such as a temperature cycle.

Accordingly, what is needed in the art is a integrated circuit device and method for manufacturing thereof that addresses the above discussed issues.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a sectional view of one embodiment of an exemplary integrated circuit.

FIG. 2 is a sectional view of one embodiment of a liquid crystal display (LCD) device within which the integrated circuit of FIG. 1 may be incorporated.

FIG. 3 is a table illustrating a set of IC chip failure rates.

### DETAILED DESCRIPTION

The present disclosure relates generally to microelectronic devices and methods of manufacturing thereof and, more specifically, to a microelectronic device packaged using Chip On Glass (COG) technology.

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

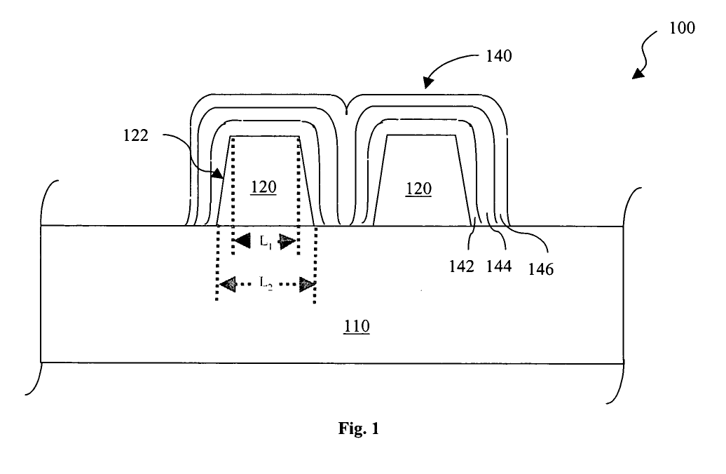

FIG. 1 is a sectional view of one embodiment of an exemplary integrated circuit 100. The integrated circuit 100 comprises a semiconductor substrate 110. The semiconductor substrate 110 may use an elementary semiconductor such as crystal silicon, polycrystalline silicon, amorphous silicon, germanium, and diamond, a compound semiconductor such as silicon carbide and gallium arsenic, or an alloy semiconductor such as SiGe, GaAsP, AlInAs, AlGaAs, GaInP, or any combination thereof.

The semiconductor substrate 110 may further include a variety of electric devices formed in the semiconductor substrate using semiconductor manufacturing technologies. These electric devices may be isolated from each other in the substrate through varieties of technologies including dielectric isolation (such as local oxidation of silicon-LOCOS and shallow trench isolation-STI), junction isolation, and field isolation. These electric devices may include, but are not limited to, passive components such as resistors, capacitors, and inductors, active components such as metal-oxide-semiconductor field effect transistors (MOSFETs), bipolar transistors, high power transistors, high frequency transistors, memory cells, or combinations thereof. The semiconductor manufacturing technologies involved to fabricate the same may include complementary MOS (CMOS) technologies, bipolar and CMOS (BiCMOS) technologies, or bipolar, CMOS, and double diffused metal-oxide-semiconductor (DMOS) technologies which is referred to as BCD, or other proper manufacturing technologies.

The semiconductor substrate 110 may further include a multilayer interconnect to route and link the electric devices to form functional circuits. Such formed functional integrated circuits may be used in varieties of applications. For example, the integrated circuits may be used as a liquid crystal display (LCD) driver IC, which is referred to as an LDI. The integrated circuits may be used for applications having Chip On Glass (COG) packaging involved. The multilayer interconnect may comprise aluminum, aluminum/silicon/copper alloy, titanium, titanium nitride, tungsten, polysilicon, metal silicide, or combinations as used in 0.18 μm or larger technology nodes. Aluminum interconnects may be deposited by sputtering, chemical vapor deposition (CVD), or combinations thereof. Other manufacturing processes, including photolithography and etching, may be used to pattern conductive materials for vertical (via and contact) and horizontal connects (conductive line). Still other manufacturing processes such as thermal annealing may be used to form metal silicide. The copper multilayer interconnect may comprise copper, copper alloy, titanium, titanium nitride, tantalum, tantalum nitride, tungsten, polysilicon, metal silicide, or combinations as used for 0.18 μm or less technology nodes. The copper multilayer interconnect may be formed using a dual damascene process. The metal silicide used in multilayer interconnects may include nickel silicide, cobalt silicide, tungsten silicide, tantalum silicide, titanium silicide, platinum silicide, erbium silicide, palladium silicide, or combinations thereof. The multilayer interconnects may be further isolated from each other by interlevel dielectric (ILD). The ILD may comprise silicon dioxide, fluoride-doped silicate glass (FSG), polyimide, spin-on glass (SOG), Black Diamond® (a product of Applied Materials of Santa Clara, Calif.), Xerogel, Aerogel, amorphous fluorinated carbon, Parylene, BCB, Flare, and SiLK, and/or other materials, and may be formed by CVD, atomic layer deposition (ALD), physical vapor deposition (PVD), spin-on coating and/or other processes.

The integrated circuit 100 further comprises a top metal layer 120. The top metal layer 120 may be considered as a portion of the multilayer interconnects. The top metal layer 120 may be formed using materials and manufacturing processes substantially similar to those described for the multilayer interconnects. For example, the top metal layer 120 may comprise an aluminum/copper/silicon alloy formed by sputtering. The top metal layer may further comprise titanium and titanium nitride as an adhesion and diffusion barrier layer overlying the aluminum alloy. The titanium nitride may also function as an anti-reflective coating (ARC) film to enhance resolution in a following photolithography process for patterning the top metal layer.

The conductive line in the top metal layer 120 has a tapered cross-sectional profile. The metal line in the top metal layer 120 has a top width L₁ and a bottom width L₂. wherein the top width L₁ is less than the bottom width L₂. In one embodiment, the top width L₁ is about 90% or less than the bottom width L₂. In another example, the taper profile may be defined by a tilt angle of a side outline 122 of the metal line in the top metal layer 120. The side outline 122 may have an inward tilting angle from a vertical line to more than three degrees near to the bottom. The tapered top metal lines may be formed using the above-mentioned methods. For example, an aluminum metal line may be fabricated to have a tapered profile by adjusting etching processing parameters such as content and ratio of etching solutions in wet etching and etching gas in dry etching. In another example that may be used for a dual damascene process, an interlayer dielectric layer may be etched to have a tapered trench and then be filled in by copper. The interlayer dielectric may be etched using wet etching first and then dry etching by gradually changing the etch method and adjusting etching parameters.

The integrated circuit 100 may further comprise a passivation structure 140 wherein the passivation structure has three passivation layers labeled as a first passivation layer 142, a second passivation layer 144, and a third passivation layer 146, respectively. The first passivation layer 142 may be in direct contact with the top metal layer 120. The second passivation layer 144 overlays the first passivation layer 142. The third passivation layer 146 overlays the second passivation layer 144. The passivation structure 140 may protect underlying devices, including the multilayer interconnect, from contaminants and moisture.

One embodiment is described below as an example. The first passivation layer 142 may comprise silicon oxide. For example, the silicon oxide may be phosphorous doped glass (PSG) deposited by CVD. The second passivation layer 144 may comprise silicon nitride. The silicon nitride may be formed by a CVD process such as plasma enhanced CVD (PECVD). The second passivation layer may comprise silicon oxynitride in another embodiment. The third passivation layer may comprise silicon oxide. The silicon oxide in the third passivation layer may be substantially similar to the silicon oxide of the first passivation layer in terms of deposition processes and materials. The third passivation layer may also use other materials providing a proper sealing function and less stress. In the present example, a trench between metal lines in a corner where the metal lines make a turn has a trench width about 1.4 times wider than the normal trench width. The total thickness of three passivation layers may be larger than about 0.7 times of trench width between two neighbor lines in the top metal lines. This thickness ensures sufficient filling-in and a substantially flat passivation surface.

The passivation structure 140 may have a plurality of openings to expose a set of special metal patterns, referred to as bonding pads. For applications such as Chip On Glass (COG), Under-Bump-Metallization (UBM) may be further formed on the bonding pads.

In a conventional passivation structure, the passivation structure may only have two layers, such as silicon oxide as a bottom passivation layer and silicon nitride as a top passivation layer. The silicon nitride may have a high stress level and may be subject to cracking. Further, a conventional top metal line may have an undercut feature in the trench bottom. The undercut metal profile may lead to poor step coverage of the passivation film. The poor step coverage plus the intrinsic high stress in silicon nitride may lead to failures of the passivation structure and loss of the layer's sealing function. Such a failure could be accelerated in a harsh environment and qualification/reliability tests such as temperature cycling. One such failure example is an LCD driving IC (LDI) chip bonded to a glass substrate using anisotropic conductive film (ACF) in COG technology. The LDI chip may be damaged by acid from ACF through defects in the passivation structure, which may lead to functional failure.

In the present disclosure, the tapered profile of the top metal line may enhance the step coverage of the passivation structure in the bottom corner of a trench formed between two top metal lines, reduce passivation defects, and strengthen the passivation structure. Furthermore, the third passivation layer fills in the trench between two metal lines after the first two passivation layers and provides a substantially flat passivation surface and a stronger seal to protect the underlying metal features from moisture, contamination, and acid. Because the third passivation layer has enough thickness to fill in the trenches between metal lines and has less stress than that of silicon nitride, the passivation structure may be substantially enhanced and reinforced. The tapered metal profile and the three-layer passivation may be implemented separately or together according to quality and reliability requirements of each application.

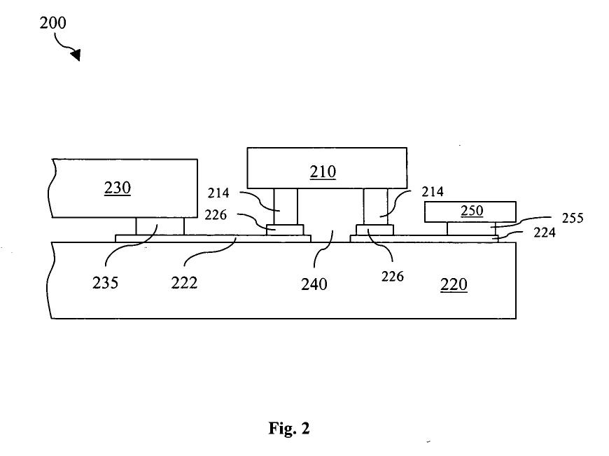

Referring to FIG. 2, illustrated is a sectional view of one embodiment of an LCD device 200 in which the integrated circuit 100 of FIG. 1 may be incorporated. The LCD device 200 is only one example of a device in which the integrated circuit 100 with a strengthened passivation structure may be used. The LCD device 200 may comprise an IC chip 210 having a structure similar to the integrated circuit 100 illustrated in FIG. 1. The IC chip 210 may have a tapered top metal line, a three-layer passivation structure, or a combination thereof. The IC chip 210 may be a LCD driving IC. The IC chip 210 may further include bump features 214. The bump features may have multiple layers of different metals such as an adhesion layer, a diffusion barrier layer, a solderable layer, and an oxidation barrier layer. The bump features may comprise titanium, chromium, aluminum, copper, nickel, vanadium, gold, or combinations.

The LCD device 200 includes a LCD glass substrate 220 and an upper glass 230. The LCD glass substrate 220 may also have a plurality of glass electrodes 222 and 224 formed on the surface of the LCD glass substrate to control LC cells. The upper glass 230 may also have a plurality of glass electrodes substantially similar to 222 and 224 to control LC cells. Liquid crystal material is filled between the LCD glass substrate 220 and the upper glass 230 and sealed. The LCD glass substrate 220 and the upper glass 230 comprise translucent or transparent glass and may each further include a polarizer layer and an alignment layer (not shown). The glass electrodes are patterned and connected to each LCD cell and control the cell's display functions. The glass electrodes 222 and 224 may comprise a transparent conductive material such as indium tin oxide (ITO). The glass electrodes in the upper glass 230 may be electrically routed to the LCD glass substrate 220 through a conductive crossover feature 235 or a plurality of crossover features. The glass electrodes may include bonding features 226 configured for IV chip bonding.

The IC chip 210 may be bonded to the LCD glass substrate 220 through the bumps 214 and the bonding features 224 using an anisotropic conductive film (ACF) 240. The ACF is a thermo-set epoxy system that includes conductive particles uniformly distributed in a non-conductive adhesive film.

The LCD device 200 may further include a flexible printed circuit (FPC) 250 bonded to glass electrodes 224 of the LCD glass substrate 220 through another bonding feature 255 at one end and connected to equipment such as a display controller at another end.

It is understood that the LCD device 200 demonstrates one of many possible applications of the integrated circuit 100 (and also the IC chip 210). The integrated circuit 100 with its strengthened passivation structure may be used with other devices and/or systems where ACF or/and COG technologies are involved. The integrated circuit 100 may further extend its application to environments where a strengthened passivation structure is needed.

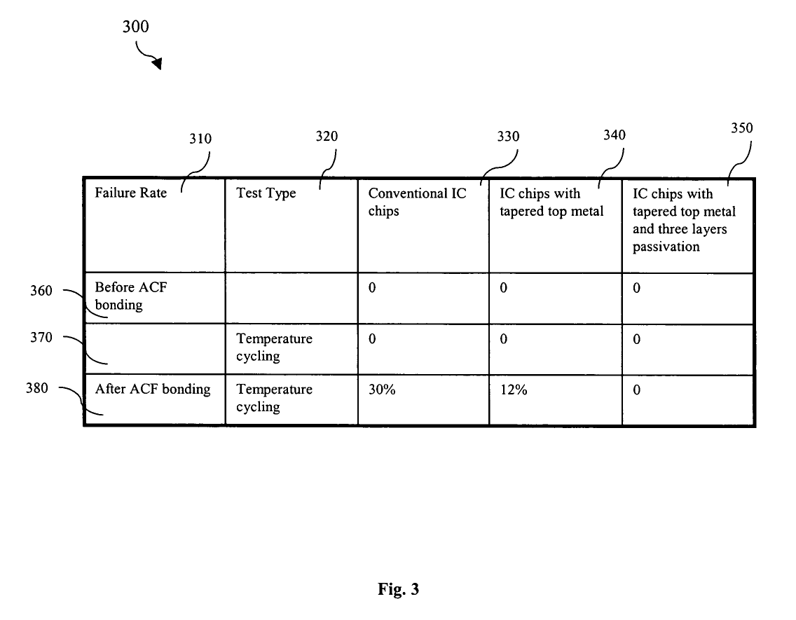

FIG. 3 is a table 300 of exemplary IC chip failure rates. The table 300 presents one set of failure rates extracted from experimental data. Failure rate 310 is defined as a ratio between a number of failed samples and a number of total tested samples. Failure is determined by predefined functional tests. The test type 320 includes temperature cycling. The experimental samples of IC chips comprise three categories: conventional IC chips 330, IC chips with a tapered top metal line 340, and IC chips with both a tapered top metal and three-layer passivation 350. The failure rates are collected for each set of samples at different stages of assembly and testing, including before ACF bonding and without temperature cycling 360, before ACF bonding and after temperature cycling 370, and after ACF bonding and after temperature cycling 380. As illustrated by the experimental data, all failures happened after ACF bonding. Temperature cycling accelerated failures through thermal stress cycling. The conventional IC chips 330 have about 30% failure rate. The IC chips with the tapered top metal 340 have a reduced failure rate of about 12%. The IC chips with both the tapered top metal and three-layer passivation 350 have about 0% failure rate. Accordingly, the use of both a tapered top metal and three-layer passivation may minimize or eliminate the failure rate.

Although embodiments of the present disclosure have been described in detail, those skilled in the art should understand that they may make various changes, substitutions and alterations herein without departing from the spirit and scope of the present disclosure. Accordingly, all such changes, substitutions and alterations are intended to be included within the scope of the present disclosure as defined in the following claims. In the claims, means-plus-function clauses are intended to cover the structures described herein as performing the recited function and not only structural equivalents, but also equivalent structures.

1. An integrated circuit comprising:
a semiconductor substrate;
a multilevel interconnect structure formed on the semiconductor substrate, wherein top metal lines of the multilevel interconnect structure forms a tapered profile; and
a multilayer passivation structure overlying the top metal lines.

2. The integrated circuit of claim 1 wherein the taper profile is defined by a less than about 90 percentage ratio between an upper width and a bottom width of the top metal lines.

3. The integrated circuit of claim 1 wherein the top metal lines includes aluminum alloy, titanium, titanium nitride, or combinations thereof.

4. The integrated circuit of claim 3 wherein the top metal lines are deposited by sputtering processing.

5. The integrated circuit of claim 1 wherein the top metal lines include copper, metal, tantalum, tantalum nitride, or combinations thereof.

6. The integrated circuit of claim 5 wherein the top metal lines are deposited by a plurality of processes including sputtering and plating.

7. The integrated circuit of claim I wherein the multilayer passivation structure comprises a first, second, and third passivation layers, wherein the second passivation layer is positioned between the first and third passivation layers, and wherein the first passivation layer is in direct contact with the top metal line.

8. The integrated circuit of claim 7 wherein a total thickness of the first, second, and third passivation layers is larger than about 0.7 times of a trench width between two neighboring lines of the top metal lines.

9. The integrated circuit of claim 7 wherein the first passivation layer comprises silicon oxide.

10. The integrated circuit of claim 7 wherein the second passivation layer comprises silicon nitride.

11. The integrated circuit of claim 7 wherein the second passivation layer comprises silicon oxynitride.

12. The integrated circuit of claim 7 wherein the third passivation layer comprises silicon oxide.

13. The integrated circuit of claim 9 and claim 12 wherein the silicon oxide is deposited by chemical vapor deposition (CVD).

14. The integrated circuit of claim 10 and claim 11 wherein the silicon nitride and silicon oxynitride are deposited by CVD.

15. The integrated circuit of claim 1 wherein the integrated circuit is packaged using Chip On Glass (COG) technology.

16. The integrated circuit of claim 15 wherein the COG technology bonds the integrated circuit to a glass using an anisotropic conductive film (ACF).

17. The integrated circuit of claim 1 further comprising a liquid crystal display (LCD) driving module.

18. The integrated circuit of claim I wherein the semiconductor substrate comprises materials selected from the group consisting of silicon, germanium, diamond, silicon carbide, gallium arsenic, gallium phosphide, indium phosphide, indium arsenide, indium antimonide, SiGe, GaAsP, AlInAs, AlGaAs, GaInAs, GaInP, and GaInAsP.

19. An integrated circuit comprising;
a semiconductor substrate;
a multilevel interconnect structure formed on the semiconductor substrate; and
a multilayer passivation structure having at least three passivation layers and overlaying the multilevel interconnect structure.

20. The integrated circuit of claim 19 wherein a total thickness of the three passivation layers is larger than about 0.7 times of a distance between two neighboring top metal lines in the multilayer passivation structure.

21. The integrated circuit of claim 19 wherein the three passivation layers comprise:
a first passivation layer having a first silicon oxide layer;
a second passivation layer having a nitrogen-containing layer and overlaying the first passivation layer; and
a third passivation layer having a second silicon oxide layer and overlaying the second passivation layer.

22. The integrated circuit of claim 21 wherein the nitrogen-containing layer comprises silicon nitride.

23. The integrated circuit of claim 21 wherein the nitrogen-containing layer comprising silicon nitride, silicon oxynitride, or combinations thereof.

24. The integrated circuit of claim 21 wherein the first, second, and third passivation layers are deposited by a plurality of chemical vapor deposition (CVD) processing steps.

25. The integrated circuit of claim 19 wherein the integrated circuit is mounted to a glass by an anisotropic conductive film (ACF) using Chip On Glass (COG) technology.
